(19) United States
(12) Patent Application Publication
(10) Pub. No.: US 2005/0181619 A1
(43) Pub. Date: Aug. 18, 2005

(54) Method for forming metal oxide layer by nitric acid oxidation

(75) Inventors: Jenn-Gwo Hwu, Taipei City (TW); Chih-Sheng Kuo, Taipei City (TW); Szu-Wei Huang, Taipei City (TW)

Correspondence Address: Haverstock & Owens LLP, 162 North Wolfe Road, Sunnyvale, CA, 94086, US

(73) Assignee: National Taiwan University

(21) Appl. No.: 10/778,780

(22) Filed: Feb. 12, 2004

(51) Int. Cl. H01L 21/302; H01L 21/461

(52) U.S. Cl. 438/745

(57) ABSTRACT

A method for forming a metal oxide layer by a nitric acid oxidation is disclosed. The method comprises steps of: a) providing a substrate, b) forming an ultra-thin silicon dioxide layer on the substrate, c) forming a metal layer on the silicon dioxide layer, d) oxidizing the metal layer into the metal oxide layer by the nitric acid oxidation, and e) annealing the metal oxide layer.

### FIELD OF THE INVENTION

This invention relates to a method for forming a metal oxide layer, and more particularly to a method for forming a metal oxide layer by a nitric acid oxidation.

### BACKGROUND OF THE INVENTION

The current CMOS manufacturing technology is in the age of nano-element, and the more advanced nano-manufacturing technology (<100 nm) is acceleratedly developed and is close to the mass production. With the progression of the manufacturing technology, the number of the transistors per chip is increasing, the size of the transistor is getting smaller, and the gate oxide layer of the transistor is getting thinner. For the conventional gate oxide layer of silicon dioxide, the leakage current in the accumulation region is increasing exponentially with the thickness decrease of the gate oxide layer. To suppress the leakage current and provide higher gate capacitance, the study of using a metal oxide layer with high dielectric constant (high-k) to substitute the conventional gate oxide layer of silicon dioxide is of great urgency. Compared with the conventional gate oxide layer of silicon dioxide, the metal oxide layer with the same equivalent oxide thickness (EOT) has lower leakage current and higher gate capacitance. For low power elements, the lower leakage current can reduce the static power dissipation, and the higher gate capacitance can increase the channel-control efficiency. Therefore, the high-k gate dielectric material becomes the most promising semiconductor technique of the next generation.

The techniques for growing the ultra-thin high-k metal oxide layer include thermal oxidation, atomic layer deposition (ALD), chemical vapor deposition (CVD), molecular beam epitaxy (MBE), and jet vapor deposition (JVD). For thermal oxidation, a layer of metal or metal compound is deposited on the substrate first and is then thermally oxidized into a metal oxide layer. This method is simple and convenient, but it has to be performed at high temperature. For ALD, CVD, MBE and JVD, the metal oxide layer can be directly grown on the substrate, but these methods need expensive equipments to provide highly vacuumed condition at high temperature, which cost a lot. Therefore, it is necessary to provide a method for forming a metal oxide layer without the need of high temperature or highly vacuumed condition to reduce the production cost.

### SUMMARY OF THE INVENTION

It is an object of the present invention to provide a method for forming a metal oxide layer by a nitric acid oxidation.

It is another object of the present invention to provide a method for forming a MOS field effect transistor having a high-k gate dielectric.

In accordance with an aspect of the present invention, the method for forming a metal oxide layer by a nitric acid oxidation comprises steps of: a) providing a substrate, b) forming an ultra-thin silicon dioxide layer on the substrate, c) forming a metal layer on the silicon dioxide layer, d) oxidizing the metal layer into the metal oxide layer by the nitric acid oxidation, and e) annealing the metal oxide layer.

Preferably, the substrate is formed of a semiconductor material selected from a group consisting of Si, SiC, SiₓGe₁₋ₓ and GaAs.

Preferably, the ultra-thin silicon dioxide layer has a thickness less than 1 nm.

Preferably, the step b) is performed in one of a furnace and a rapid thermal oxidation (RTO) machine.

Preferably, the step b) is performed by a chemical liquid phase deposition (LPD).

Preferably, the step c) is performed by a process selected from a group consisting of sputtering, evaporation, chemical vapor deposition (CVD) and molecular beam epitaxy (MBE).

Preferably, an oxide of the metal has a high dielectric constant (high-k) more than 3.9 times permittivity in free space.

Preferably, the metal is one selected from a group consisting of Al, Ti, La, Zr, Ta and Hf.

Preferably, the step d) is performed with a diluted nitric acid.

Preferably, the diluted nitric acid is diluted with a liquid selected from a group consisting of water and chemicals compatible with the nitric acid.

Preferably, the diluted nitric acid is formed by mixing the nitric acid with water in a ratio of 1:1˜1:49.

Preferably, the step e) is performed in an annealing gas.

Preferably, the annealing gas is one selected from a group consisting of N₂, O₂, NH₃, N₂O and forming gas (90% N₂+10% H₂).

Preferably, the step e) is performed by a furnace annealing with an annealing temperature between 400˜900° C. and an annealing time between 1˜90 minutes.

Preferably, the step e) is performed by a rapid thermal annealing with an annealing temperature between 400˜1000° C. and an annealing time between 1˜90 seconds.

In accordance with another aspect of the present invention, the method for forming a MOS field effect transistor having a high-k gate dielectric comprises steps of: a) providing a P-type substrate having an N-well and a field oxide isolating the N-well and the P-type substrate, b) forming an ultra-thin silicon dioxide layer on the substrate, c) forming a metal layer on the silicon dioxide layer, d) oxidizing the metal layer into a metal oxide layer as a gate oxide layer by an nitric acid oxidation, e) annealing the gate oxide layer, f) forming a gate electrode layer on the gate oxide layer, g) defining a gate area, and h) forming a drain region and a source region by an ion implantation.

The method further comprises steps of: i) forming an oxide insulating layer on the substrate having the gate area, the drain region and the source region, j) forming windows of the gate area, the drain region and the source region by etching, and k) defining a contact wire and reducing an interface trap concentration by a post metallization annealing.

Preferably, the substrate is formed of a semiconductor material selected from a group consisting of Si, SiC, SiₓGe₁₋ₓ and GaAs.

Preferably, the ultra-thin silicon dioxide layer has a thickness less than 1 nm.

Preferably, the step b) is performed in one of a furnace and a rapid thermal oxidation (RTO) machine.

Preferably, the step b) is performed by a chemical liquid phase deposition (LPD).

Preferably, the step c) is performed by a process selected from a group consisting of sputtering, evaporation, chemical vapor deposition (CVD) and molecular beam epitaxy (MBE).

Preferably, the metal has an oxide having a high dielectric constant (high-k) more than 3.9 times permittivity in free space.

Preferably, the metal is one selected from a group consisting of Al, Ti, La, Zr, Ta and Hf.

Preferably, the step d) is performed with a diluted nitric acid.

Preferably, the diluted nitric acid is diluted with a liquid selected from a group consisting of water and chemicals compatible with the nitric acid.

Preferably, the diluted nitric acid is formed by mixing the nitric acid with water in a ratio of 1:1˜1:49.

Preferably, the step e) is performed in an annealing gas.

Preferably, the annealing gas is one selected from a group consisting of N₂, O₂, NH₃, N₂O and forming gas (90% N₂+10% H₂).

Preferably, the step e) is performed by a furnace annealing with an annealing temperature between 400˜900° C. and an annealing time between 1˜90 minutes.

Preferably, the step e) is performed by a rapid thermal annealing with an annealing temperature between 400˜1000° C. and an annealing time between 1˜90 seconds.

The above objects and advantages of the present invention will become more readily apparent to those ordinarily skilled in the art after reviewing the following detailed description and accompanying drawings, in which:

### BRIEF DESCRIPTION OF THE DRAWINGS

FIGS. 1(A) to (D) show the method for forming the metal oxide layer according to a preferred embodiment of the present invention;

FIGS. 2(A) to (G) show the method for forming a MOS field effect transistor having a high-k gate dielectric according to another preferred embodiment of the present invention;

FIG. 3 shows the variation of the gate current of the MOS capacitor under a constant voltage;

FIG. 4 shows the current-voltage (I-V) characteristic of the MOS capacitor;

FIG. 5 shows the comparison of the capacitance difference at high frequency and low frequency under flat-band voltage of the high-k gate dielectric with and without the ultra-thin silicon dioxide layer as the buffering interface;

FIG. 6 shows the comparison of the leakage current of the present oxide layer annealed in O₂ or N₂ with that of the conventional silicon dioxide layer; and

FIG. 7 shows the I-V characteristic of the aluminum oxide on SiC substrate at different annealing temperature.

### DETAILED DESCRIPTION OF THE PREFERRED EMBODIMENT

The present invention uses a high-k metal oxide layer to substitute the conventional silicon dioxide layer as the gate oxide layer, in which an ultra-thin silicon dioxide buffering interface is used to effectively avoid the generation of metal silicide between the high-k gate dielectric layer and the substrate. The manufacturing process of the present invention is to grow an ultra-thin silicon dioxide film on the semiconductor substrate as a buffering interface, and deposit an ultra-thin metal film, which is then oxidized into a metal oxide layer by a nitric acid oxidation and thermally annealed to increase the quality of the oxide layer. The method for forming the metal oxide layer of the present invention is illustrated in detail as follows.

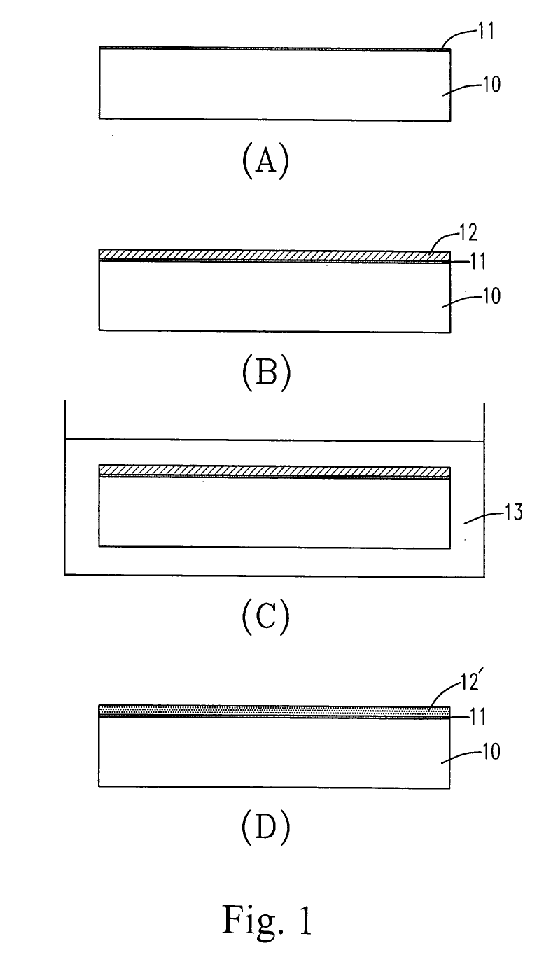

Please refer to FIGS. 1(A) to (D) showing the method for forming the metal oxide layer according to a preferred embodiment of the present invention. First, a clean semiconductor substrate 10 is provided, in which the substrate can be Si, SiC, SiₓGe₁₋ₓ, GaAs, or other semiconductor substrate that can be used for growing a metal oxide. Subsequently, an ultra-thin silicon dioxide film 11 (less than 1 nm) is grown from the semiconductor substrate 10 in a furnace or a rapid thermal oxidation (RTO) machine, or by a liquid phase deposition (LPD) process. An ultra-thin metal film 12 is then deposited on the ultra-thin silicon dioxide film 11 by sputtering, evaporation, chemical vapor deposition (CVD) or molecular beam epitaxy (MBE), in which the metal can be Al, Ti, La, Zr, Ta, Hf, or other metal whose oxide has higher dielectric constant more than 3.9 times permittivity in free space. The metal film 12 is oxidized into a metal oxide layer 12′ by a diluted nitric acid, which is diluted with water or other chemicals compatible with the nitric acid. For example, the diluted nitric acid can be formed by mixing the nitric acid with water in a ratio of 1:1˜1:49 (preferably 1:19). After that, the metal oxide layer 12′ is thermally annealed to increase the quality of the oxide layer. In which, the annealing gas can be N₂, O₂, NH₃, N₂O or forming gas (90% N₂+10% H₂). If it is performed by a furnace annealing, the annealing temperature is between 400˜900° C. and the annealing time is between 1˜90 minutes. If it is performed by a rapid thermal annealing, the annealing temperature is between 400˜1000° C. and the annealing time is between 1˜90 seconds. Finally, the native oxide on the back of wafer is removed with hydrofluoric acid, and an aluminum metal is evaporated thereon as a back contact of the wafer, so that the whole component is completely formed. The equivalent oxide thickness (EOT) of the formed aluminum oxide thin film is 18 angstrom.

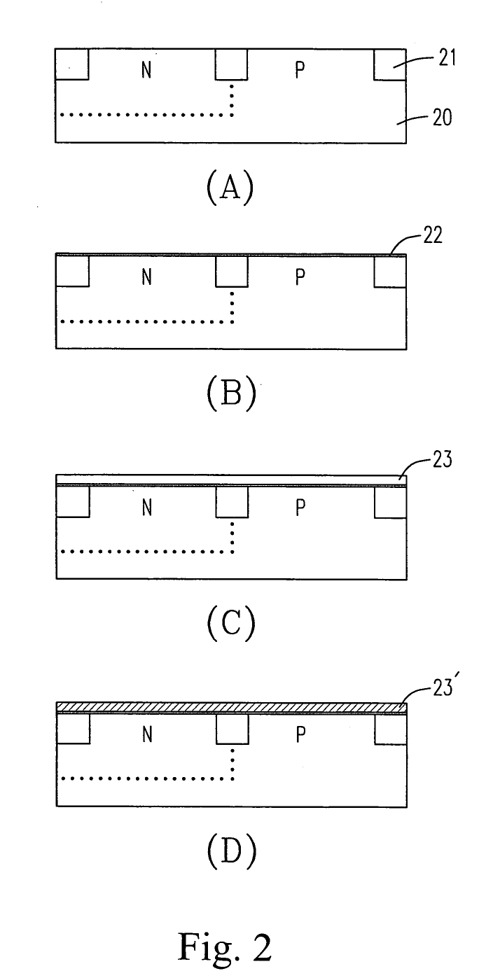

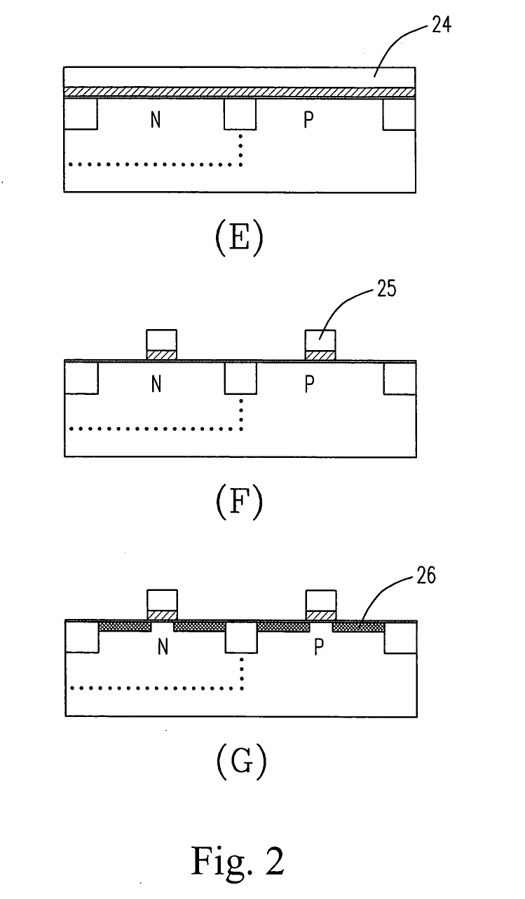

Please refer to FIGS. 2(A) to (G) showing the method for forming a MOS field effect transistor having a high-k gate dielectric according to another preferred embodiment of the present invention. First, a P-type substrate 20 having an N-well and a field oxide 21 isolating the N-well and the P-type substrate is provided. Subsequently, an ultra-thin silicon dioxide film 22 is deposited on the semiconductor substrate 20, and an aluminum metal (99.9999%) thin film 23 of 10 angstrom is evaporated on the ultra-thin silicon dioxide film 22. Then the aluminum metal thin film 23 is oxidized with diluted nitric acid (HNO₃:H₂O=1:19) for 1 minute to form a metal oxide layer 23′ of aluminum oxide. The metal oxide layer 23′ is further annealed in a furnace in N₂ at 650° C. for 30 minutes to accomplish the formation of the oxide layer. An aluminum metal (99.9999%, 3000 angstrom) is evaporated on the metal oxide layer 23′ to be served as a gate dielectric layer 24, in which a gate electrode 25 (with an area of 2.25×10⁻⁴ cm²) is defined there from by photolithography. For forming a MOS field effect transistor (MOSFET), a drain/source electrode 26 of the transistor is formed by ion implantation after the formation of the gate electrode 25. An oxide insulation layer is deposited and further etched to define windows for the gate, drain, and source electrodes. Then a contact wire is defined at the gate, drain, and source electrodes to form a MOSFET, which is further post metallization annealed to reduce the interface trap concentration.

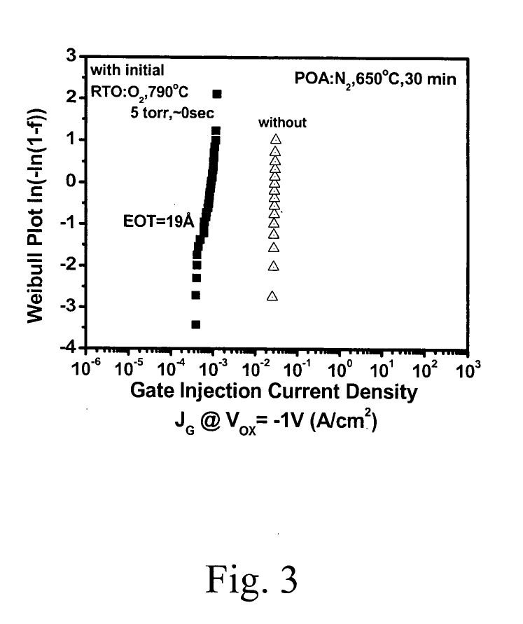

FIG. 3 shows the variation of the gate current of the MOS capacitor under a constant voltage. For studying the importance of the ultra-thin silicon dioxide layer as a buffering interface with a high-k gate dielectric, a constant oxide voltage (=V_{G}−V_{FB}) of −1V is applied onto the aluminum oxide MOS capacitor to observe the variation of the gate injection current density. As shown in FIG. 3, the device without the ultra-thin silicon dioxide layer as the buffering interface would result in a great increase of the gate leakage current, since the metal oxide contains lots of electron and hole traps. On the contrary, if the ultra-thin silicon dioxide layer is grown as the buffering interface in advance, the gate leakage current is significantly reduced. Therefore, the buffering interface is important to the improvement of the quality of the dielectric layer.

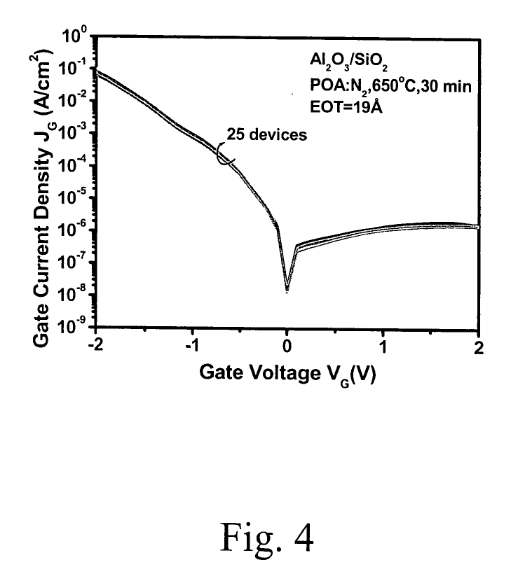

FIG. 4 shows the current-voltage (I-V) characteristic of the MOS capacitor. The I-V characteristics of 25 aluminum oxide MOS capacitors with the equivalent oxide thickness (EOT) of 19 angstrom formed by the method of the present invention are measured. As a result, the measured values of the 25 components are substantially on the same curve, which shows the high uniformity of the manufacturing method of the present invention. In addition, a saturated current is obtained after entering the depletion region, and such saturated current would not cause the great decline of the channel mobility.

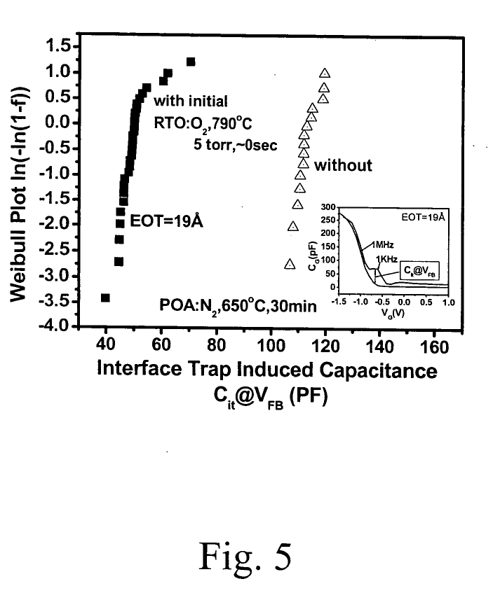

FIG. 5 shows the comparison of the capacitance difference at high frequency (1 MHz) and low frequency (1 KHz) under flat-band voltage of the high-k gate dielectric with or without the ultra-thin silicon dioxide layer as the buffering interface. As shown in FIG. 5, for interface control, the interface trap of the interface with the buffering oxide layer is lower than that without the buffering interface, which further improves the importance of the buffering interface to the improvement of the quality of the dielectric layer after the nitric acid oxidation.

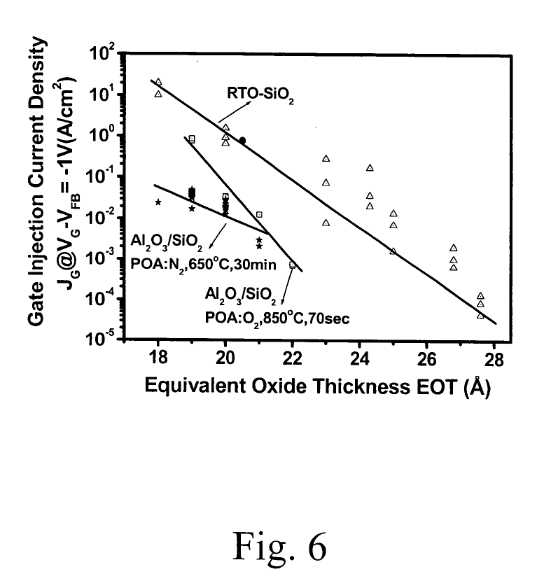

FIG. 6 shows the comparison of the leakage current of the present oxide layer annealed in O₂ or N₂ with that of the conventional silicon dioxide layer. It is shown that the present invention provides a stable manufacturing process, and the present oxide layer with different equivalent oxide thickness (EOT) has less leakage current than the conventional silicon dioxide layer. In addition, the thinnest equivalent oxide thickness (EOT) can reach to 18 angstrom.

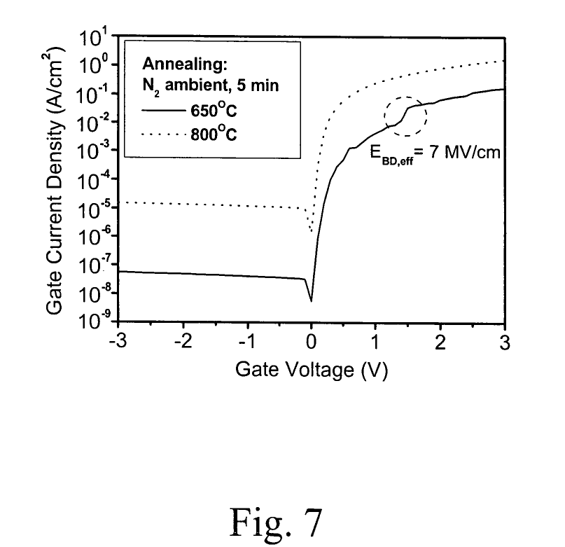

FIG. 7 shows the I-V characteristic of the aluminum oxide on SiC substrate at different annealing temperatures. The aluminum oxide formed on N type 4H—SiC substrate by the nitric acid oxidation has an equivalent oxide thickness (EOT) of 26 angstrom, and an equivalent breakdown field of 5.77 MV/cm that is comparable with Si₃N₄ on 4H—SiC.

The present invention utilizes a low-cost physical vapor deposition and thermal evaporation to evaporate a metal layer on the substrate, and utilizes a nitric acid oxidation technique with optimal oxidation concentration, temperature and time to completely oxidize the metal into a metal oxide layer, and then the metal oxide layer is further thermally annealed. Compared with other techniques, the manufacturing process of the present invention can be performed at room temperature without any expensive equipment, and has no need to be grown in a highly vacuumed condition (<10⁻⁷ torr). Therefore, the manufacturing process of the present invention can effectively reduce the production cost and the thermal budget for the growth environment, and is compatible with the current manufacturing equipments and conditions.

In conclusion, the present invention employs a room temperature nitric acid oxidation technique to oxidize the metal film, which can grow the ultra-thin (EOT<20 angstrom) and high quality gate oxide layer, and can be directly integrated with the current CMOS manufacturing process without changing any manufacturing parameters and steps, so as to achieve the objective of miniaturization of the components.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method for forming a metal oxide layer by a nitric acid oxidation, comprising steps of:
a) providing a substrate;
b) forming an ultra-thin silicon dioxide layer on said substrate;
c) forming a metal layer on said silicon oxide layer;
d) oxidizing said metal layer into said metal oxide layer by said nitric acid oxidation; and
e) annealing said metal oxide layer.

2. The method according to claim 1 wherein said substrate is formed of a semiconductor material selected from a group consisting of Si, SiC, SiₓGe₁₋ₓ and GaAs.

3. The method according to claim 1 wherein said ultra-thin silicon dioxide layer has a thickness less than 1 nm.

4. The method according to claim 1 wherein said step b) is performed in one of a furnace and a rapid thermal oxidation (RTO) machine.

5. The method according to claim 1 wherein said step b) is performed by a chemical liquid phase deposition (LPD).

6. The method according to claim 1 wherein said step c) is performed by a process selected from a group consisting of sputtering, evaporation, chemical vapor deposition (CVD) and molecular beam epitaxy (MBE).

7. The method according to claim 1 wherein an oxide of said metal has a high dielectric constant (high-k) more than 3.9 times permittivity in free space.

8. The method according to claim 1 wherein said metal is one selected from a group consisting of Al, Ti, La, Zr, Ta and Hf.

9. The method according to claim 1 wherein said step d) is performed with a diluted nitric acid.

10. The method according to claim 9 wherein said diluted nitric acid is diluted with a liquid selected from a group consisting of water and chemicals compatible with said nitric acid.

11. The method according to claim 9 wherein said diluted nitric acid is formed by mixing said nitric acid with water in a ratio of 1:1˜1:49.

12. The method according to claim 1 wherein said step e) is performed in an annealing gas.

13. The method according to claim 12 wherein said annealing gas is one selected from a group consisting of N₂, O₂, NH₃, N₂O and forming gas (90% N₂+10% H₂).

14. The method according to claim 1 wherein said step e) is performed by a furnace annealing with an annealing temperature between 400˜900° C. and an annealing time between 1˜90 minutes.

15. The method according to claim 1 wherein said step e) is performed by a rapid thermal annealing with an annealing temperature between 400˜1000° C. and an annealing time between 1˜90 seconds.

16. A method for forming a MOS field effect transistor having a high-k gate dielectric, comprising steps of:
a) providing a P-type substrate having an N-well and a field oxide isolating said N-well and said P-type substrate;
b) forming an ultra-thin silicon dioxide layer on said substrate;
c) forming a metal layer on said silicon dioxide layer;
d) oxidizing said metal layer into a metal oxide layer as a gate oxide layer by an nitric acid oxidation;
e) annealing said gate oxide layer;
f) forming a gate electrode layer on said gate oxide layer;
g) defining a gate area; and
h) forming a drain region and a source region by an ion implantation.

17. The method according to claim 16 further comprising steps of:
i) forming an oxide insulating layer on said substrate having said gate area, said drain region and said source region;
j) forming windows of said gate area, said drain region and said source region by etching; and
k) defining a contact wire and reducing an interface trap concentration by a thermal annealing.

18. The method according to claim 16 wherein said substrate is formed of a semiconductor material selected from a group consisting of Si, SiC, SiₓGe₁₋ₓ and GaAs.

19. The method according to claim 16 wherein said ultra-thin silicon dioxide layer has a thickness less than 1 nm.

20. The method according to claim 16 wherein said step b) is performed in one of a furnace and a rapid thermal oxidation (RTO) machine.

21. The method according to claim 16 wherein said step b) is performed by a chemical liquid phase deposition (LPD).

22. The method according to claim 16 wherein said step c) is performed by a process selected from a group consisting of sputtering, evaporation, chemical vapor deposition (CVD) and molecular beam epitaxy (MBE).

23. The method according to claim 16 wherein said metal has an oxide having a high dielectric constant (high-k) more than 3.9 times permittivity in free space.

24. The method according to claim 16 wherein said metal is one selected from a group consisting of Al, Ti, La, Zr, Ta and Hf.

25. The method according to claim 16 wherein said step d) is performed with a diluted nitric acid.

26. The method according to claim 25 wherein said diluted nitric acid is diluted with a liquid selected from a group consisting of water and chemicals compatible with said nitric acid.

27. The method according to claim 25 wherein said diluted nitric acid is formed by mixing said nitric acid with water in a ratio of 1:1˜1:49.

28. The method according to claim 16 wherein said step e) is performed in an annealing gas.

29. The method according to claim 28 wherein said annealing gas is one selected from a group consisting of N₂, O₂, NH₃, N₂O and forming gas (90% N₂+10% H₂).

30. The method according to claim 16 wherein said step e) is performed by a furnace annealing with an annealing temperature between 400˜900° C. and an annealing time between 1˜90 minutes.

31. The method according to claim 16 wherein said step e) is performed by a rapid thermal annealing with an annealing temperature between 400˜1000° C. and an annealing time between 1˜90 seconds.
